(19) United States
(12) Patent Application Publication
(10) Pub. No.: US 2013/0319333 A1
(43) Pub. Date: Dec. 5, 2013

(54) Injector and Material Layer Deposition Chamber Including the Same

(71) Applicant: Samsung Electronics Co., Ltd., Gyeonggi-do (KR)

(72) Inventors: Jin-sub Lee, Gyeonggi-do (KR); Min-seok Kim, Gyeonggi-do (KR); Jung-sub Kim, Gyeonggi-do (KR); Cheol-soo Sone, Seoul (KR)

(21) Appl. No.: 13/909,466

(22) Filed: Jun. 4, 2013

(30) Foreign Application Priority Data
Jun. 4, 2012 (KR) 10-2012-0059913

(51) Int. Cl. C23C 16/455; B05B 1/00

(52) U.S. Cl. CPC C23C 16/455; B05B 1/005
USPC 118/730; 239/548

(57) ABSTRACT

An injector and a material layer deposition chamber including the same. An injector includes: a plurality of independent sections; and a gas inlet and a gas outlet that are provided in each of the plurality of independent sections, wherein gas outlets provided in two adjacent sections are positioned and configured to inject gas in a limited and different direction relative to each other.

### CROSS-REFERENCE TO RELATED APPLICATIONS

This application claims the benefit of and priority to Korean Patent Application No. 10-2012-0059913, filed on Jun. 4, 2012, the disclosure of which is hereby incorporated by reference herein in its entirety.

### FIELD

The inventive concept relates to equipment for forming a material layer, and more particularly, to an injector used to deposit a material layer of a semiconductor device and a material layer deposition chamber including the injector.

### BACKGROUND

Semiconductor devices such as light-emitting devices (LEDs) include a plurality of material layers. The plurality of material layers may include an aluminum nitride (AlN) layer.

AlN is stable at high temperatures and has high thermal and electrical conductivity. Also, AlN has a wide band gap. Accordingly, AlN is drawing attention as a next-generation material.

The higher crystallinity of an AlN layer used as a material layer of a semiconductor device, the better characteristics of the AlN layer.

However, when a low-temperature metalorganic chemical vapor deposition (MOCVD) growth method is used, adatoms of aluminum (Al), that is, atoms adsorbed onto a surface of a substrate on which the Al is deposited, have less mobility than gallium (Ga). Accordingly, a migration length of the adatoms is short. Accordingly, it may be difficult to form a high quality AlN layer by using a two-dimensional (2D) growth method. Although a migration-enhanced epitaxy (MEE) growth method has been used to ensure a sufficient migration length of Al, the MEE growth method has a problem in that a growth rate is reduced and it is difficult to control a valve. Also, since the MEE growth method alternately supplies an Al source gas and a nitrogen (N) source gas, it may take a relatively long time to deposit an AlN layer.

### SUMMARY

The inventive concept according to some embodiments provides an injector that may keep the advantage of a conventional migration-enhanced epitaxy (MEE) growth method and overcome the disadvantage of the conventional MEE growth method such as a low growth rate and a long deposition time.

The inventive concept according to some embodiments also provides a material layer deposition chamber including the injector.

According to an aspect of the inventive concept, there is provided an injector including: a plurality of independent sections; and a gas inlet and a gas outlet that are provided in each of the plurality of independent sections, with each gas outlet provided on a side surface of a respective independent section; wherein gas outlets provided in two adjacent sections from among the plurality of independent sections are positioned and configured to inject gas in a limited and different direction relative to each other.

The injector may be a single-layer structure, or a multi-layer structure.

The plurality of independent sections may be two, three, or four independent sections.

When the injector has a single-layer structure, from among the plurality of independent sections, a section to which a first gas is supplied and a section to which a second gas is supplied may be disposed such that a direction in which the first gas is injected and a direction in which the second gas is injected are opposite or substantially opposite to each other.

The multi-layer structure may include a lower section, an intermediate section, and an upper section which are sequentially stacked, wherein gases supplied to the upper section and the lower section are different from a gas supplied to the intermediate section.

Gases may be injected from the upper section and the lower section in the same direction or in substantially the same direction.

The gas outlet may be formed only in a portion of a side surface of each of the lower section, the intermediate section, and the upper section.

According to another aspect of the inventive concept, there is provided a material layer deposition chamber including: an injector; and a rotatable wafer stage that allows wafers to be loaded thereon to surround the injector, wherein the injector includes: a plurality of independent sections; and a gas inlet and a gas outlet that are provided in each of the plurality of independent sections, with each gas outlet provided on a side surface of a respective independent section; wherein gas outlets provided in two adjacent sections from among the plurality of independent sections are positioned and configured to inject gas in a limited and different direction relative to each other.

According to another aspect of the inventive concept, there is provided an injector including: a generally cylindrical injector structure formed from a plurality of independent sections, each of the plurality of independent sections including a gas inlet and a gas outlet, the gas outlet of each of the plurality of independent sections provided on an arcuate side surface of the independent section; wherein the gas outlet of a first one of the independent sections is configured to inject gas in a limited first direction, and wherein the gas outlet of a second, adjacent one of the independent sections is configured to inject gas in a limited second direction that is different from the first direction.

According to embodiments of the inventive concept, the injector includes a plurality of independent sections to which components of a material layer to be formed are independently supplied, and components of the material layer supplied to two adjacent sections are injected in different directions. A direction in which a gas is injected may be “limited” (i.e., less than 360 degrees). For example, when the injector takes the form of a cylindrical structure having an outer periphery, a particular independent section may provide for the injection of gas outwardly away from the structure along a limited or relatively small angular portion or arc length of the outer periphery. In some embodiments, the direction in which gas is injected from a respective independent section may be limited by an outer arc length of the respective section and/or by the arrangement and/or orientation of gas outlet(s) provided in the respective section. For example, in some embodiments wherein four independent sections having an equal outer arc length of 90 degrees form the injector, the direction in which gas is injected from each independent section may be limited to 90 degrees or less depending on the arrangement and/or orientation of gas outlet(s) associated with the independent section.

Accordingly, the components of the material layer injected from the injector have reduced risk of reacting with each other in the air, and all of the injected components may react on a substrate.

As such, since components are injected in different directions, a direction in which a gas is injected is limited, and components react only on a substrate, a growth rate (G/R) of a material layer may be increased and the material layer having high quality may be grown. Also, since the components may be simultaneously injected, a time taken to form the material layer may be shorter than a conventional MEE growth method in which components are alternately supplied.

### BRIEF DESCRIPTION OF THE DRAWINGS

Exemplary embodiments of the inventive concept will be more clearly understood from the following detailed description taken in conjunction with the accompanying drawings in which:

FIG. 1 is a perspective view illustrating an injector according to embodiments of the inventive concept;

FIG. 2 is a plan view illustrating an injector having two sections according to some embodiments;

FIG. 3 is a plan view illustrating an injector having three sections according to some embodiments;

FIG. 4 is a cross-sectional view illustrating an injector according to other embodiments of the inventive concept; and

FIG. 5 is a plan view illustrating a material layer deposition chamber including an injector, according to embodiments of the inventive concept.

### DETAILED DESCRIPTION OF EMBODIMENTS OF THE INVENTIVE CONCEPT

The inventive concept will now be described more fully with reference to the accompanying drawings, in which exemplary embodiments of the inventive concept are shown. Thicknesses of layers or regions in the drawings are exaggerated for clarity. The inventive concept may, however, be embodied in many different forms and should not be construed as limited to the embodiments set forth herein; rather, these embodiments are provided so that this disclosure will be thorough and complete, and will fully convey the scope of the inventive concept to those skilled in the art.

It will be understood that when an element is referred to as being “coupled” or “connected” to another element, it can be directly coupled or connected to the other element or intervening elements may also be present. In contrast, when an element is referred to as being “directly coupled” or “directly connected” to another element, there are no intervening elements present. Like numbers refer to like elements throughout.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the expression “and/or” includes any and all combinations of one or more of the associated listed items.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It is noted that any one or more aspects or features described with respect to one embodiment may be incorporated in a different embodiment although not specifically described relative thereto. That is, all embodiments and/or features of any embodiment can be combined in any way and/or combination. Applicant reserves the right to change any originally filed claim or file any new claim accordingly, including the right to be able to amend any originally filed claim to depend from and/or incorporate any feature of any other claim although not originally claimed in that manner. These and other objects and/or aspects of the inventive concept are explained in detail in the specification set forth below.

First, injectors according to the inventive concept will be explained.

FIG. 1 is a perspective view illustrating an injector (hereinafter, referred to as a first injector) 30 according to embodiments of the inventive concept.

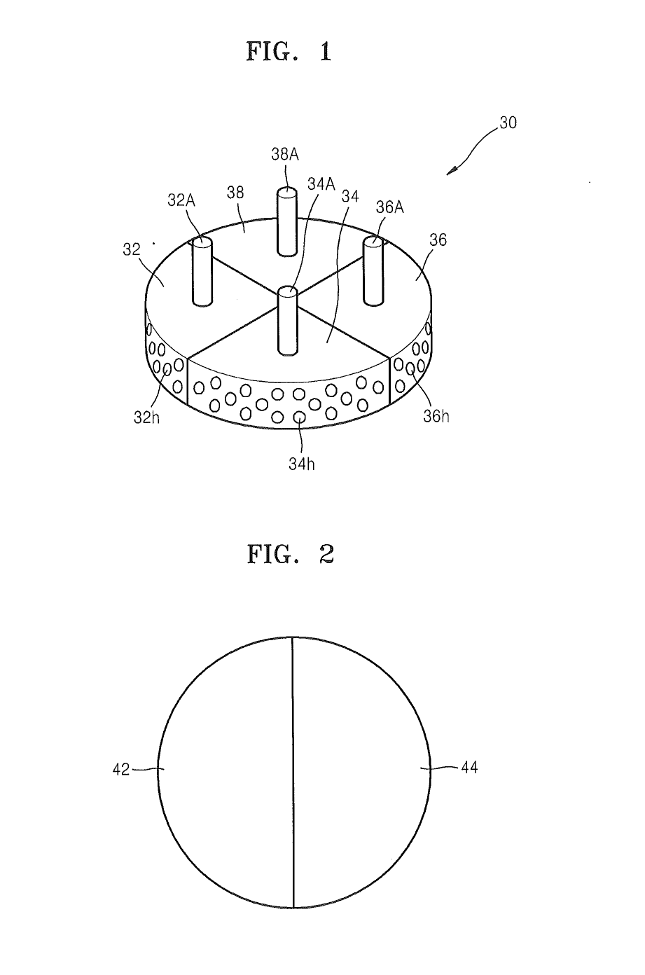

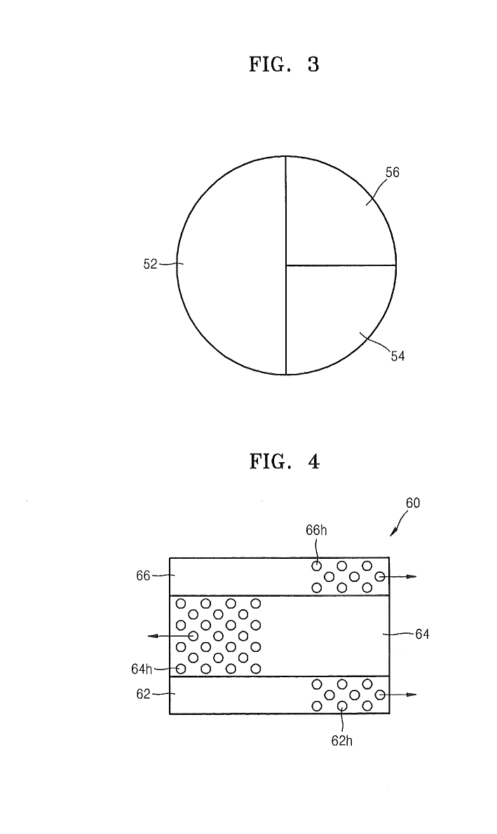

Referring to FIG. 1, the first injector 30 may have a cylindrical single-layer structure. The first injector 30 may have a single-layer structure including first through fourth sections 32, 34, 36, and 38. Although the first injector 30 includes four sections, that is, the first through fourth sections 32, 34, 36, and 38 in FIG. 1, the present embodiment is not limited thereto, and the first injector 30 may include a different number of sections, such as two or three sections as shown in FIGS. 2 and 3.

Source gases having different components may be respectively supplied to the first through fourth sections 32, 34, 36, and 38. The source gases respectively supplied to the first through fourth sections 32, 34, 36, and 38 may be gases including components that constitute a material layer to be formed, or reactive gases that cause the components to react with each other. For example, when the material layer includes two components, that is, first and second components, a first source gas including the first component of the material layer may be supplied to the first section 32 and a second source gas including the second component of the material layer may be supplied to the third section 36. If an additional reactive gas is required for a reaction between the first and second components, the additional reactive gas may be supplied to the second section 34 or the fourth section 38. The material layer may be, for example, an aluminium nitride (AlN) layer. When the material layer is an AlN layer, the first source gas may be an aluminium (Al) source gas, for example, trimethylaluminum (TMAl). The second source gas may be a nitrogen (N) source gas, for example, ammonia (NH₃). The material layer may be one of a plurality of material layers constituting a light-emitting device. The material layer may be one of a plurality of material layers constituting a semiconductor device.

A first gas supply pipe 32A is connected to the first section 32. A second gas supply pipe 34A is connected to the second section 34. A third gas supply pipe 36A is connected to the third section 36. A fourth gas supply pipe 38A is connected to the fourth section 38. The first source gas is supplied to the first section 32 through the first gas supply pipe 32A. The second source gas is supplied to the third section 36 through the third gas supply pipe 36A. A supply rate of a source gas or a reactive gas supplied through each supply pipe may be appropriately adjusted according to a type and components of a material layer to be formed and a growth rate.

A plurality of first gas outlets (injection holes) 32h through which a source gas supplied through the first gas supply pipe 32A is injected are formed in a side surface of the first section 32. The plurality of first gas outlets 32h may be uniformly distributed throughout the side surface of the first section 32. A diameter of each of the plurality of first gas outlets 32h may range from, for example, about 1 mm to about 10 mm.

A plurality of second gas outlets (injection holes) 34h are formed in a side surface of the second section 34. The second gas outlets 34h may be uniformly distributed. A diameter of each of the second gas outlets 34h may be equal to or different from a diameter of each of the first gas outlets 32h.

A plurality of third and fourth gas outlets (not shown) are also formed in side surfaces of the third and fourth sections 36 and 38, respectively. The third and fourth gas outlets may be uniformly distributed throughout the side surfaces of the third and fourth sections 36 and 38, respectively, and each of the diameters of the third and fourth gas outlets may be equal to or different from a diameter of each of the first gas outlets 32h.

The first injector 30 may have a single-layer structure including only two sections, that is, first and second sections 42 and 44, as shown in FIG. 2. Alternatively, the first injector 30 may have a single-layer structure including only three sections, that is, first through third sections 52, 54, and 56, as shown in FIG. 3.

A gas supply pipe (not shown) is connected to each of the sections 42, 44, 52, 54, and 56 of FIGS. 2 and 3, and a plurality of gas outlets (not shown) are formed in a side surface of each of the sections 42, 44, 52, 54, and 56.

FIG. 4 is a cross-sectional view illustrating an injector (hereinafter, referred to as a second injector) 60 according to other embodiments of the inventive concept.

Referring to FIG. 4, the second injector 60 may have a cylindrical structure, and includes three sections, that is, a lower section 62, an intermediate section 64, and an upper section 66, which are sequentially stacked. The lower section 62 and the upper section 66 may have the same or substantially the same structure. The intermediate section 64 may be different from the upper and lower sections 66 and 62. The lower section 62 and the upper section 66 may be sections for injecting the second source gas described with reference to FIG. 1. The intermediate section 64 may be a section for injecting the first source gas described with reference to FIG. 1.

A plurality of fifth gas outlets 62h are formed in a portion of a side surface of the lower section 62. The fifth gas outlets 62h may be uniformly distributed throughout the portion of the side surface of the lower section 62, and a diameter of each of the fifth gas outlets 62h may be equal to or different from a diameter of each of the first gas outlets 32h. A plurality of sixth gas outlets 64h are formed in a portion of a side surface of the intermediate section 64. A diameter of each of the sixth gas outlets 64h may be equal to or different from a diameter of each of the fifth gas outlets 62h. The portion in which the sixth gas outlets 64h are formed may be different in terms of direction from the portion in which the fifth gas outlets 62h are formed. Accordingly, a direction in which a source gas is injected from the lower section 62 may be different from a direction in which a source gas is injected from the intermediate section 64. In various embodiments, the direction in which a source gas is injected from the lower section 62 may be opposite, generally opposite, or substantially opposite from the direction in which a source gas is injected from the intermediate section 64.

A plurality of seventh gas outlets 66h are uniformly formed in a portion of a side surface of the upper section 66. A diameter of each of the seventh gas outlets 66h may be equal to or different from a diameter of each of the fifth gas outlets 62h. The portion in which the seventh gas outlets 66h are formed may be the same or substantially the same in terms of a direction as the portion in which the fifth gas outlets 62h are formed. Accordingly, a direction in which a source gas is injected from the lower section 62 may be the same or substantially the same as a direction in which a source gas is injected from the upper section 66. A gas supply pipe (not shown) for supplying a gas is connected to each of the lower section 62, the intermediate section 64, and the upper section 66.

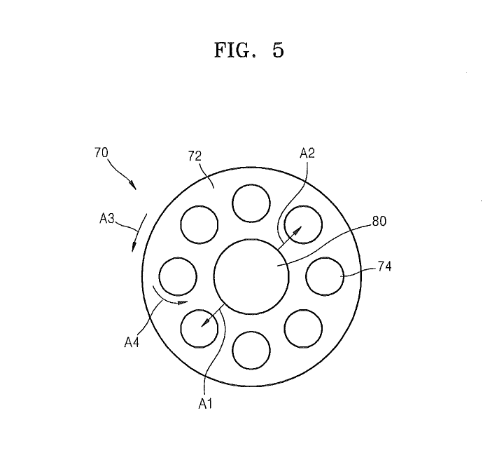

FIG. 5 is a plan view illustrating a material layer deposition chamber 70 according to embodiments of the inventive concept.

Referring to FIG. 5, the material layer deposition chamber 70 includes a wafer stage 72. A plurality of wafers 74 are loaded on the wafer stage 72. The plurality of wafers 74 are arranged in an annular shape. An injector 80 is disposed at or near the center of the wafer stage 72 in the annular arrangement of the plurality of wafers 74. Once a material layer starts to be deposited, the wafer stage 72 rotates about the injector 80, as indicated by the outer direction arrow A3. Independently of the rotation of the wafer stage 72, each of the plurality of wafers 74 may rotate, as indicated by the inner direction arrow A4 for an exemplary one of the wafers 74. The injector 80 may be the first injector 30 of FIG. 1 or the second injector 60 of FIG. 4.

In FIG. 5, a first arrow indicates a direction Al in which a first source gas, for example, an Al source gas, is injected from the injector 80 onto the wafers 74, and a second arrow indicates a direction A2 in which a second source gas, for example, a N source gas, is injected. In some embodiments, the direction A2 is generally opposite to the direction Al. In some embodiments, the direction A2 is substantially opposite to the direction Al. In some embodiments, the direction A2 is directly opposite to the direction Al (i.e., the directions Al and A2 are 180 degrees apart).

While the inventive concept has been particularly shown and described with reference to exemplary embodiments thereof, it will be understood that various changes in form and details may be made therein without departing from the spirit and scope of the following claims.

What is claimed is:

1. An injector, comprising:
a plurality of independent sections; and
a gas inlet and a gas outlet that are provided in each of the plurality of independent sections;
wherein gas outlets provided in two adjacent sections from among the plurality of independent sections are positioned and configured to inject gas in a limited and different direction relative to each other.

2. The injector of claim 1, wherein the injector has a single-layer structure.

3. The injector of claim 2, wherein from among the plurality of independent sections, a section to which a first gas is supplied and a section to which a second gas is supplied are disposed such that a direction in which the first gas is injected and a direction in which the second gas is injected are substantially opposite to each other.

4. The injector of claim 1, wherein the plurality of independent sections are two, three, or four independent sections.

5. The injector of claim 1, wherein the injector has a multi-layer structure.

6. The injector of claim 5, wherein the multi-layer structure comprises a lower section, an intermediate section, and an upper section which are sequentially stacked,
wherein gases supplied to the upper section and the lower section are different from a gas supplied to the intermediate section.

7. The injector of claim 6, wherein the gases are injected from the upper section and the lower section in the same direction.

8. The injector of claim 6, wherein the gas outlet is formed only in a portion of a side surface of each of the lower section, the intermediate section, and the upper section.

9. The injector of claim 1, wherein the gas outlet of each respective independent section comprises a plurality of injector holes.

10. A material layer deposition chamber, comprising:
an injector, comprising:
a plurality of independent sections; and
a gas inlet and a gas outlet that are provided in each of the plurality of independent sections, each gas outlet provided on a side surface of a respective independent section;
wherein gas outlets provided in two adjacent sections from among the plurality of independent sections are positioned and configured to inject gas in a limited and different direction relative to each other; and
a rotatable wafer stage that allows wafers to be loaded thereon to surround the injector, wherein the injector is disposed substantially at a center of the wafer stage.

11. The material layer deposition chamber of claim 10, wherein the injector has a single-layer structure.

12. The material layer deposition chamber of claim 11, wherein from among the plurality of independent sections, a section to which a first gas is supplied and a section to which a second gas is supplied are disposed such that a direction in which the first gas is injected and a direction in which the second gas is injected are generally opposite to each other.

13. The material layer deposition chamber of claim 10, wherein the plurality of independent sections are two, three, or four independent sections.

14. The material layer deposition chamber of claim 10, wherein the injector has a multi-layer structure.

15. The material layer deposition chamber of claim 14, wherein the multi-layer structure comprises a lower section, an intermediate section, and an upper section which are sequentially stacked,
wherein gases supplied to the upper section and the lower section are different from a gas supplied to the intermediate section.

16. The material layer deposition chamber of claim 15, wherein the gases are injected from the upper section and the lower section in substantially the same direction.

17. The material layer deposition chamber of claim 14, wherein the gas outlet is formed only in a portion of a side surface of each of the lower section, the intermediate section, and the upper section.

18. The material layer deposition chamber of claim 10, wherein the wafer stage is configured such that wafers loaded thereon are individually rotatable.

19. The material layer deposition chamber of claim 10, wherein the gas outlet of each respective independent section comprises a plurality of injector holes.

20. An injector, comprising:
a generally cylindrical injector structure formed from a plurality of independent sections, each of the plurality of independent sections including a gas inlet and a gas outlet, the gas outlet of each of the plurality of independent sections provided on an arcuate side surface of the independent section;
wherein the gas outlet of a first one of the independent sections is configured to inject gas in a limited first direction, and wherein the gas outlet of a second, adjacent one of the independent sections is configured to inject gas in a limited second direction that is different from the first direction.
